(19) United States
(12) Patent Application Publication
(10) Pub. No.: US 2012/0111625 A1
(43) Pub. Date: May 10, 2012

(54) Printed circuit board and method for filling via hole thereof

(75) Inventors: Kwangok Jeong, Gyeonggi-do (KR); Hyoseung Nam, Gyeonggi-do (KR)

(73) Assignee: SAMSUNG ELECTRO-MECHANICS CO., LTD., Suwon (KR)

(21) Appl. No.: 13/317,291

(22) Filed: Oct. 14, 2011

(30) Foreign Application Priority Data
Nov. 9, 2010 (KR) 10-2010-0110962
Nov. 18, 2010 (KR) 10-2010-0115007

(51) Int. Cl. H05K 1/11; H01K 3/10

(52) U.S. Cl. 174/264; 29/852

(57) ABSTRACT

Disclosed herein is a method for filling a via hole of a printed circuit board, the method including: a dividing step of dividing a via hole that is to be formed in a base substrate into a predetermined number; a first via forming step of forming a first divided via by primarily processing portions of the divided via hole; a first filling step of filling the formed first divided via with a metal; a second via forming step of forming a second divided via by secondarily processing other portions of the divided via hole; and a second filling step of filling the formed second divided via with a metal to fill the via hole, thereby making it possible to fill the via hole without a dimple.

### CROSS REFERENCE(S) TO RELATED APPLICATIONS

This application claims the benefit under 35 U.S.C. Section 119 of Korean Patent Application Serial Nos. 10-2010-0115007 and 10-2010-0110962, entitled “Printed Circuit Board and Method for Filling Via Hole Thereof” filed on Nov. 18, 2010 and Nov. 9, 2010 which are hereby incorporated by reference in its entirety into this application.

### BACKGROUND OF THE INVENTION

1. Technical Field

The present invention relates to a printed circuit board and a method for filling a via hole thereof, and more particularly, to a printed circuit board in which after a via hole that is to be formed is divided into a plurality of divided vias, portions of the divided vias are primarily processed and filled and other portions of the divided vias are secondarily processed and filled, and a method for filling a via hole thereof.

2. Description of the Related Art

In accordance with the recent continuous development in miniaturization and technology integration of electronic devices and products due to high technology electronic devices and products, a process of manufacturing a printed circuit board (PCB) used for the electronic device, or the like, has also required various changes, corresponding to the miniaturization and the technology integration.

The method of manufacturing the printed circuit board has progressed from an initial single sided printed circuit board to a double sided printed circuit board and has then progressed to a multi-layered printed circuit board. Particularly, in manufacturing the multilayered printed circuit board, a manufacturing method referred to as a so-called build up method has been conducted.

Various via holes such as an inner via hole (IVH), a blind via hole (BVH), a plated through hole (PTH), or the like are formed in order to electrically interconnect electronic elements and circuit patterns in each layer during manufacturing of the multilayered printed circuit board.

A process of forming the via hole according to the related art includes forming the via hole in a substrate using a drill, performing a desmear work on a surface of the substrate and an inner peripheral surface of the via hole, and filling an inner space of the via hole with a metal.

Here, a fill plating scheme was used in order to fill the inner space of the via hole with the metal. However, it was difficult to apply the fill plating scheme to the via hole having a size larger than a predetermined size.

That is, in the case of the via hole having a large size, a large dimple was generated and it was difficult to satisfactorily plate the via hole even though the plating thickness became thick.

### SUMMARY OF THE INVENTION

An object of the present invention is to provide a printed circuit board in which after a via hole that is to be formed is divided into a plurality of divided vias, portions of the divided vias are primarily processed and filled and other portions of the divided vias are secondarily processed and filled, thereby making it possible to easily fill the via hole, and a method for filling via hole thereof.

According to an exemplary embodiment of the present invention, there is provided a method for filling a via hole of a printed circuit board, the method including: a dividing step of dividing a via hole that is to be formed in a base substrate into a predetermined number; a first via forming step of forming a first divided via by primarily processing portions of the divided via hole; a first filling step of filling the formed first divided via with a metal; a second via forming step of forming a second divided via by secondarily processing other portions of the divided via hole; and a second filling step of filling the formed second divided via with a metal to fill the via hole.

The first filling step may include fill plating the formed first divided via.

The second filling step may include fill plating the formed second divided via.

The first filling step may include: a first electroless plating layer forming step of forming a first electroless plating layer in the formed first divided via; and a first electro plating layer forming step of forming a first electro plating layer in the formed first divided via having the first electroless plating layer formed therein.

The first filling step may include a first plating resist applying step of applying a first plating resist to an opposite surface to one surface of the base substrate on which the first electroless plating layer is formed before the first electro plating layer forming step.

The first filling step may include a first peeling off step of peeling off the applied first plating resist after the first electro plating layer forming step.

The second filling step may include: a second electroless plating layer forming step of forming a second electroless plating layer in the formed second divided via; and a second electro plating layer forming step of forming a second electro plating layer in the formed second divided via having the second electroless plating layer formed therein.

The second filling step may include a second plating resist applying step of applying a second plating resist to an opposite surface to one surface of the base substrate on which the second electroless plating layer is formed before the second electro plating layer forming step.

The second filling step may include a second peeling off step of peeling off the applied second plating resist after the second electro plating layer forming step.

The first filling step may include filling the formed first divided via with a metal paste.

The second filling step may include fill plating the formed second divided via.

According to another exemplary embodiment of the present invention, there is provided a printed circuit board including: a base substrate having a via hole formed therein; first and second divided vias formed by dividing the via hole; and a metal layer filled in an inner portion of the first and second divided vias.

The first divided via may be fill plated.

The second divided via may be fill plated.

The first and second divided vias may be alternately disposed in an inner portion of the via hole.

The metal layer may include: filling metal layers filled in the first and second divided vias; and separating metal layers interposed between the first and second divided vias to separate the first and second divided vias from each other.

The separating metal layers may include: a first separating metal layer interposed in an inner portion of the first divided via; and a second separating metal layer interposed in an inner portion of the second divided via.

The first and second separating metal layers may be bonded to each other in a sawtooth shape and may be filled between the first and second divided vias.

The filling metal layer may be an electro plating layer, and the separating metal layer may be an electroless plating layer.

According to another exemplary embodiment of the present invention, there is provided a printed circuit board including: a base substrate having a via hole formed therein; and first and second divided vias formed by dividing the via hole; wherein a metal paste layer is interposed in the first divided via, and a fill plating layer is interposed in the second divided via.

The first and second divided vias may be alternately disposed in an inner portion of the via hole.

The fill plating layer may include: a filling plating layer filled in an inner portion of the second divided via; and a separating plating layer interposed between the first and second divided vias to separate the first and second divided vias from each other.

The filling plating layer may be an electro plating layer, and the separating plating layer may be an electroless plating layer.

The separating plating layer may be interposed in a sawtooth shape.

### BRIEF DESCRIPTION OF THE DRAWINGS

FIG. 1 is a cross-sectional view showing a printed circuit board according to an exemplary embodiment of the present invention;

FIG. 2 is a cross-sectional view showing a printed circuit board according to another exemplary embodiment of the present invention;

FIGS. 3 to 13 are cross-sectional views showing a process of filling a via hole of a printed circuit board according to an exemplary embodiment of the present invention;

FIGS. 14 and 15 are views showing an example of dividing a via hole into a plurality of divided vias according to a shape of the via hole; and

FIGS. 16 to 21 are cross-sectional views showing a process of filling a via hole of a printed circuit board according to another exemplary embodiment of the present invention.

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely the most preferable embodiments but do not represent all of the technical spirit of the present invention. Thus, the present invention should be construed as including all the changes, equivalents, and substitutions included in the spirit and scope of the present invention at the time of filing this application.

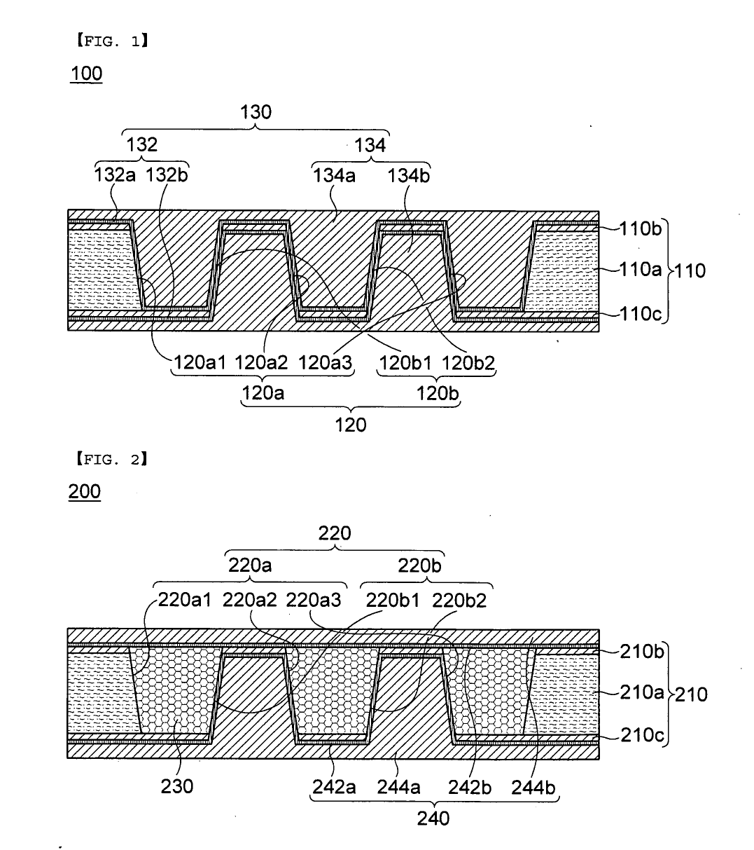

FIG. 1 is a cross-sectional view showing a printed circuit board according to an exemplary embodiment of the present invention.

As shown in FIG. 1, a printed circuit board 100 is configured to include a base substrate 110, first and second divided vias 120a and 120b, and a metal layer 130.

The base substrate 110, which is a raw material of the printed circuit board 100, has a via hole 120 formed therein.

The base substrate 110 may be formed of a copper clad laminate (CCL) or a thermosetting resin composite-impregnated glass fiber substance (a thermosetting resin composite-impregnated glass fiber reinforced prepreg). Among them, the copper clad laminate includes a single sided copper clad laminate formed by sequentially stacking an insulating layer and a copper layer and a double sided copper clad laminate formed by sequentially stacking a lower copper layer, an insulating layer, and an upper copper layer.

In addition, the via hole 120, which is a plating through hole (PTH) penetrating through the base substrate 110, may be formed at a desired position on the substrate by drilling a reference hole using an X-ray drill or a sensor drill and then performing drilling using a computer numerical control (CNC) drill based on the reference hole.

The via hole 120 may be formed using an ultraviolet (UV) laser beam, a carbon dioxide (CO₂) laser beam, or the like. Here, the laser beam is not limited thereto. The via hole 120 may be formed using various laser units.

The first and second divided vias 120a and 120b are formed by dividing the via hole 120 and are alternately disposed in an inner portion of the via hole 120.

For example, when the inner portion of the via hole 120 is divided into five divided via holes, a via hole corresponding to 120a₁, 120a₂, and 120a₃ among the five divided via holes is the first divided via 120a and a via hole corresponding to 120b₁ and 120b₂ among the five divided via holes is the second divided via 120b. That is, one via hole 120 is divided, thereby making it possible to form a plurality of divided vias 120a and 120b.

The metal layer 130: 132 and 134 is made of a metal material such as copper, nickel, tin, and the like, filled in a surface of the base substrate 110 and the inner portion of the via hole 120, that is, an inner portion of the first and second divided vias 120a and 120b, and is configured to include a filling metal layer 134: 134a and 134b and a separating metal layer 132: 132a and 132b.

The filling metal layer 134: 134a and 134b is a metal layer interposed in the inner portion of the first and second divided vias 120a and 120b, and the separating metal layer 132: 132a and 132b is a metal layer interposed between the first and second divided vias 120a and 120b to separate the first and second divided vias 120a and 120b from each other.

The separating metal layer 132: 132a and 132b is configured to include a first separating metal layer 132a formed in the inner portion of the first divided via 120a and a second separating metal layer 132b formed in the inner portion of the second divided via 120b, and the first and second separating metal layers 132a and 132b are bonded to each other in a sawtooth shape and are filled between the first and second divided vias 120a and 120b.

The metal layer 130 including the filling metal layer 134 and the separating metal layer 132 is filled by a fill plating scheme, such that it is formed of a fill plating layer.

To this end, after the separating metal layers 132a and 132b, which are electroless plating layers, are stacked on the surface of the base substrate 110 and the inner portion of the via hole 120, that is, the first and second divided vias 120a and 120b by electroless plating, the filling metal layers 134a and 134b, which are electro plating layers, are formed on the surface of the base substrate 110 and the inner portion of the first and second divided vias 120a and 120b by electro plating. Therefore, the fill plating layer 130 is formed to have a structure in which the electro plating layers (the filling metal layers) are stacked on the electroless plating layers (the separating metal layers).

Summing up the structure of the printed circuit board as described above, the first and second divided vias 120a and 120b are formed by dividing the via hole 120 in the base substrate 110 and are respectively filled by the fill plating scheme. Therefore, the filling metal layers 134a and 134b, that is, the electro plating layers are formed on the inner portion of the first and second divided vias 120a and 120b, and the separating metal layers 132a and 132b separating the first and second divided vias 120a and 120b from each other, that is, the electroless plating layers are formed between the first and second divided vias 120a and 120b.

FIG. 2 is a cross-sectional view showing a printed circuit board according to another exemplary embodiment of the present invention.

As shown in FIG. 2, a printed circuit board 200 is configured to include a base substrate 210, and first and second divided vias 220a and 220b.

The base substrate 210, which is a raw material of the printed circuit board 200, has a via hole 220 formed therein.

The base substrate 210 may be formed of a copper clad laminate (CCL) or a thermosetting resin composite-impregnated glass fiber substance (a thermosetting resin composite-impregnated glass fiber reinforced prepreg). Among them, the copper clad laminate includes the single sided copper clad laminate formed by sequentially stacking the insulating layer and the copper layer and the double sided copper clad laminate formed by sequentially stacking the lower copper layer, the insulating layer, and the upper copper layer.

In addition, the via hole 220, which is the plating through hole (PTH) penetrating through the base substrate 210, may be formed at the desired position on the substrate by drilling a reference hole using the X-ray drill or the sensor drill and then performing the drilling using the computer numerical control (CNC) drill based on the reference hole.

The via hole 220 may be formed using the ultraviolet (UV) laser beam, the carbon dioxide (CO₂) laser beam, or the like. Here, the laser beam is not limited thereto. The via hole 220 may be formed using various laser units.

The first and second divided vias 220a and 220b are formed by dividing the via hole 220 and are alternately disposed in an inner portion of the via hole 220.

For example, when the inner portion of the via hole 220 is divided into five divided via holes, a via hole corresponding to 220a₁, 220a₂, and 220a₃ among the five divided via holes is the first divided via 220a and a via hole corresponding to 220b₁ and 220b₂ among the five divided via holes is the second divided via 220b. That is, one via hole 220 is divided, thereby making it possible to form a plurality of divided vias 220a and 220b.

A metal paste layer 230 is interposed in an inner portion of the first divided via 220a of the plurality of divided vias. A process of filling the metal paste is configured to alternately perform a first operation of filling the first divided via 220a with the metal paste by moving the metal paste to the inner portion of the first divided via 220a using squeeze and a second operation of pressing the filled metal paste.

The first divided via 220a may be filled with the metal paste using various schemes other than the above-mentioned scheme in which the first divided via 220a is filled with the metal paste using the squeeze.

Meanwhile, a fill plating layer 240 is interposed on a surface of the base substrate 210 and an inner portion of the second divided via 220b. The fill plating layer 240 is made of a metal material such as copper, nickel, tin, and the like, filled in the surface of the base substrate 210 and the second divided via 220b, and is configured to include filling plating layers 244a and 244b, a separating plating layer 242a and a plating layer 242b.

The filling plating layers 244a and 244b, which are metal layers interposed on the surface of the base substrate 210 and the inner portion of the second divided via 220a, may be formed of an electro plating layer.

The separating plating layer 242a, which is a metal layer interposed between the first and second divided vias 220a and 220b to separate the first and second divided vias 220a and 220b from each other, may be formed of an electroless plating layer and has a sawtooth shape.

The plating layer 242b, which is a metal layer interposed on the surface 210b of the printed circuit board 210, may be formed of the electroless plating layer.

The fill plating layer 240 including the filling plating layers 244a and 244b, the separating plating layer 242a, and the plating layer 242b is filled by the fill plating scheme.

To this end, after the separating plating layer 242a and the plating layer 242b, which are the electroless plating layers, are stacked on the surface of the base substrate 210 and the inner portion of the via hole 220, that is, the second divided via 220b by the electroless plating, the filling plating layers 244a and 244b, which are electro plating layers, are formed on the surface of the base substrate 210 and the inner portion of the second divided via 220b by electro plating. Therefore, the fill plating layer 240 is formed to have a structured in which the electro plating layers (the filling plating layers 244a and 244b) are stacked on the electroless plating layers (the separating plating layer 242a and the plating layer 242b).

Summing up the structure of the printed circuit board as described above, the first and second divided vias 220a and 220b are formed by dividing the via hole 220 in the base substrate 210 and are respectively filled by the paste filling scheme and the fill plating scheme. Therefore, the filling plating layer 244a, that is, the electro plating layer is formed on the inner portion of the first and second divided vias 220a and 220b, and the separating plating layer 242a separating the first and second divided vias 220a and 220b from each other, that is, the electroless plating layer is formed between the first and second divided vias 220a and 220b.

Hereinafter, a process of filling a via hole of a printed circuit board according to an exemplary embodiment of the present invention will be described.

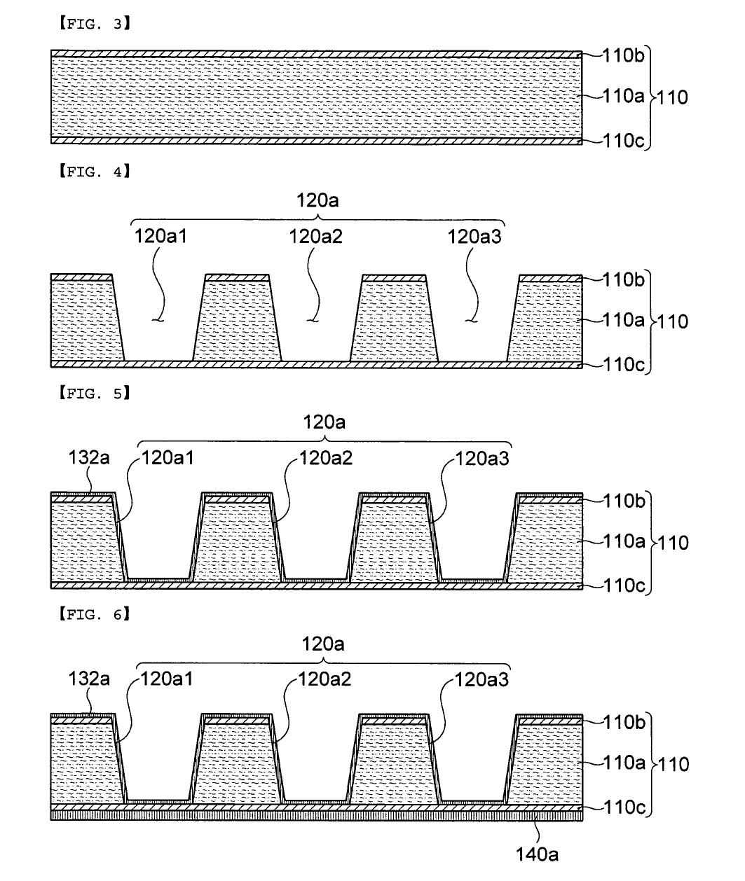

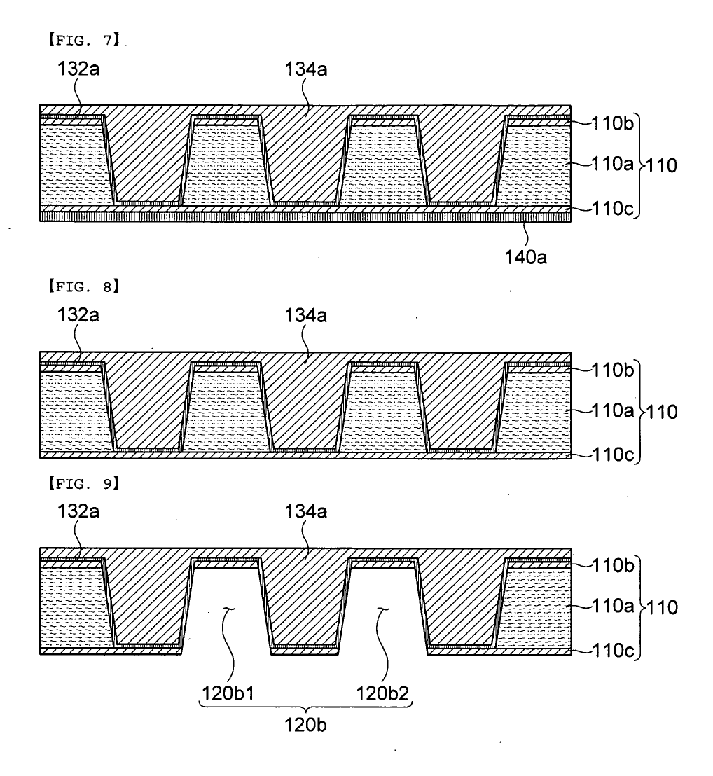

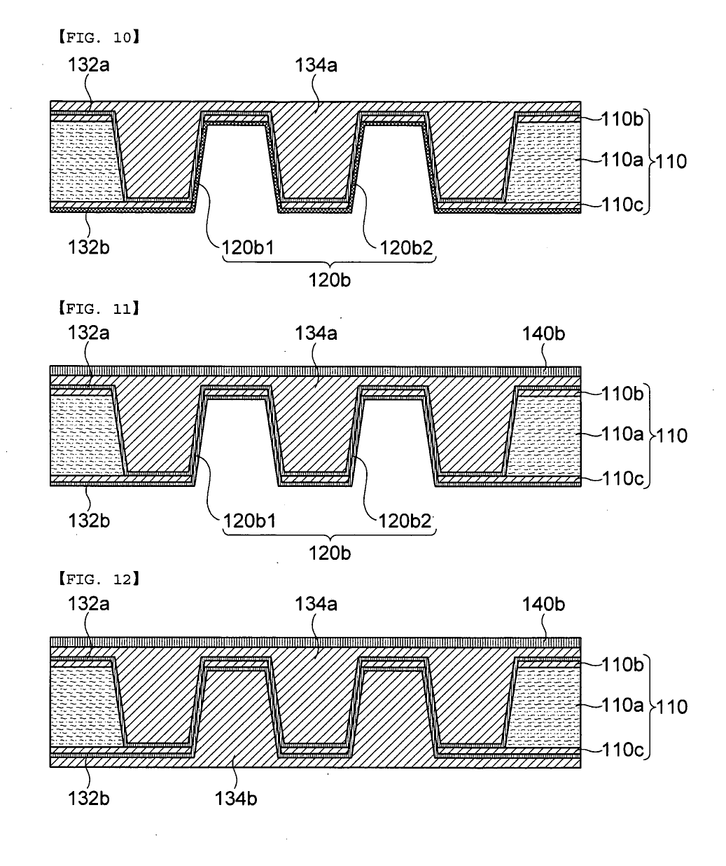

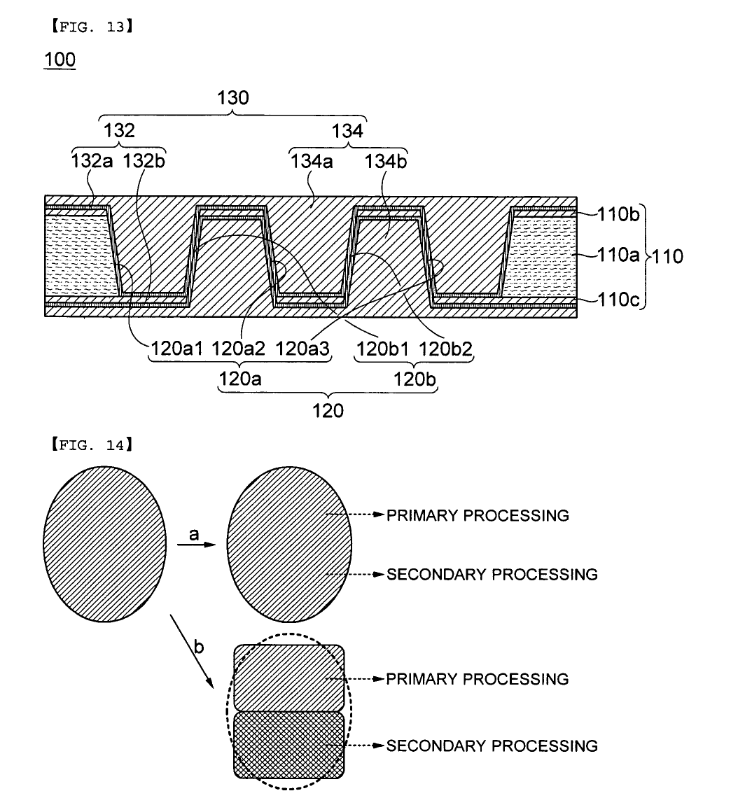

FIGS. 3 to 13 are cross-sectional views showing a process of filling a via hole of a printed circuit board according to an exemplary embodiment of the present invention.

As shown in FIGS. 3 to 13, the base substrate 110 is provided in order to manufacture the printed circuit board 100. According to an exemplary embodiment of the present invention, the copper clad laminate (CCL) is provided, the CCL including provided with thin copper layers 110b and 110c formed on both surfaces thereof, having an insulating layer 110a therebetween.

Here, the copper clad laminate 110, which is the raw material for manufacturing the printed circuit board, has a structure in which copper is thinly coated on the insulating layer. A thickness of a copper clad generally may be about 18 to 70 μm; however, may be 5 μm, 7 μm, and 15 μm in the case of a fine wiring pattern.

Then, the via hole 120 that is to be formed is divided into a predetermined number, which means that the inner portion of the via hole 120 is virtually divided in order to adjust a dividing number according to a shape and a size of the via hole 120.

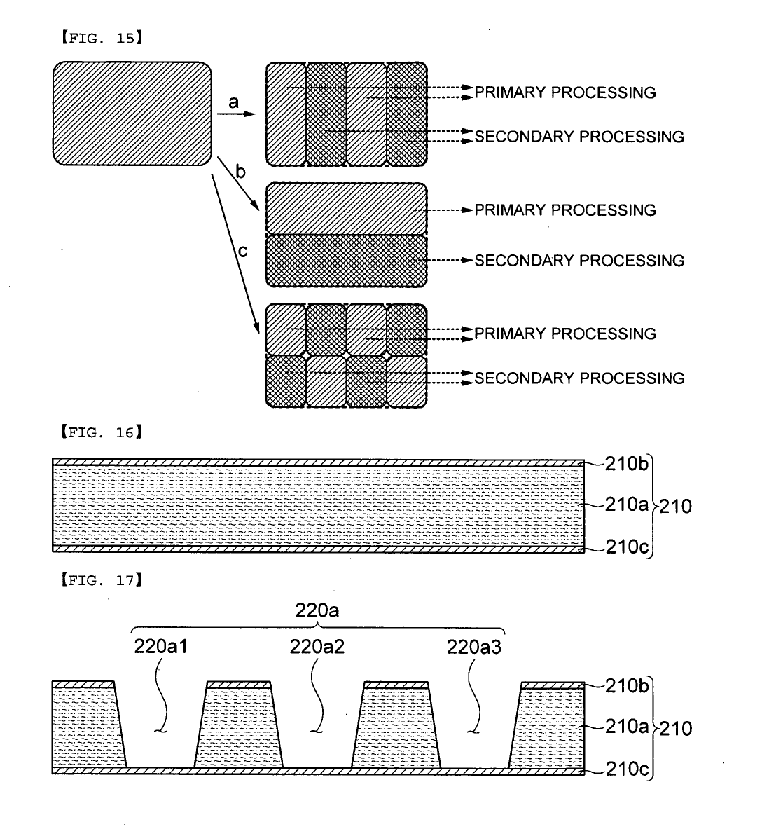

FIGS. 14 and 15, which are views showing an example of dividing a via hole into a plurality of divided vias according to a shape of the via hole, show an example of dividing the via hole into a predetermined number.

FIG. 14 shows an example of dividing the via hole 120 when the via hole 120 has a circular shape. As shown in FIGS. 14A and 14B, the via hole is transversely divided so that two divided vias are formed, one of the two divided vias is primarily processed and the other is secondarily processed.

FIG. 15 shows an example of dividing the via hole 120 when the via hole 120 has a rectangular shape. As shown in FIG. 15A, the via hole is longitudinally divided so that four divided vias are formed, two of the four divided vias are primarily processed and other two are secondarily processed. Here, the primarily processed divided via and the secondarily processed divided via are alternately arranged.

In addition, as shown in FIG. 15B, the via hole is transversally divided so that two divided vias are formed, one of the two divided vias is primarily processed and the other is secondarily processed.

Further, as shown in FIG. 15C, the via hole is transversally and longitudinally divided so that eight divided vias are formed, four of the eight divided vias are primarily processed and other four are secondarily processed. Here, the primarily processed divided via and the secondarily processed divided via are alternately arranged not to be in contact with each other.

Meanwhile, again referring to FIG. 4, portions of the divided via hole 120 are primarily processed to form the first divided via 120a: 120a₁ to 120a₃.

That is, the first divided via 120a: 120a₁ to 120a₃ is formed using a drill in a direction from an upper copper layer 110b, which is an upper surface of the copper clad laminate 110, to a lower copper layer 110c, which is a lower surface thereof.

Here, the first divided via 120a: 120a₁ to 120a₃ may be formed using any one of a mechanical drill or UV, YAG and CO₂ laser drills; however, it is preferable that the first divided via is formed at a preset position using the mechanical drill and deburring and desmear processes removing various pollutants and foreign materials are performed.

The deburring process provides roughness to the surface of the copper clad simultaneously with removing dust particles on an inner wall of the via, dust particles on a surface of the copper clad, a fingerprint, and the like, generated during the drilling, thereby increasing adhesion of the copper in the following filling process.

A resin composing the substrate is melted due to heat generated during the drilling to be attached to the inner wall of the via. The desmear process is a process of removing the melted resin attached to the substrate. The melted resin attached to the inner wall of the via significantly serves to deteriorate quality of copper plating.

As described above, after the first divided via 120a: 120a₁ to 120a₃ is formed and the deburring and desmear processes are performed, the first divided via 120a: 120a₁ to 120a₃ is filled with the metal.

According to an exemplary embodiment of the present invention, the fill plating scheme is used in order to fill the first divided via 120a: 120a₁ to 120a₃ with the metal. To this end, the first electroless plating layer 132a is formed in the copper clad laminate 110 having the first divided via 120a: 120a₁ to 120a₃ formed therein, as shown in FIG. 5. That is, the first electroless plating layer 132a is formed by performing an electroless plating process in order to provide electrical conductivity to the entire surface of the copper clad laminate and the inner portion of the first divided via 120a: 120a₁ to 120a₃.

Here, the electroless plating process, which is a process performed in order to form a seed layer for electrically copper plating the first divided via 120a: 120a₁ to 120a₃ may includes an electroless plating operation and an electrical copper plating operation.

Next, a first plating resist 140a is applied to an opposite surface to one surface of the copper clad laminate 110 on which the first electroless plating layer 132a is formed.

In a process of applying the first plating resist as described above, an etching resist (made of the same material as that of the plating resist) is selectively applied only to portions at which circuits should be formed after the plating is completed on both surfaces of the substrate, that is, circuit pattern portions. Next, an etching process is performed and the etching resist is then removed, thereby making it possible to form the circuits.

Here, the process of selectively applying the etching or plating resist may be performed by entirely applying the etching or plating resist and then performing selective etching or allowing the plating resist to selectively remain through exposure and development processes.

In addition, when the plating resist is selectively applied only to portions at which the plating should not be performed during forming of the electro plating layer, the electro plating layer is formed to have a circuit shape, thereby making it possible to form the circuits.

The circuit may be formed using various methods other than the methods described above.

Next, the electro plating process is performed on the surface of the electroless plated copper clad laminate 110 and the inner portion of the first divided via 120a: 120a₁ to 120a₃ to form the first electro plating layer 134a, thereby filling the inner portion of the first divided via 120a: 120a₁ to 120a₃ with the metal.

Here, the electroless plating process takes a long time and is complicated, such that the plating layer may not be stacked enough to obtain reliability. Therefore, the electro plating process is performed on the inner portion of the first divided via 120a: 120a₁ to 120a₃ that was previously electroless plated, thereby allowing a thickness of the plating layer to become thick.

Then, the first plating resist 140a applied to the opposite surface of the copper clad laminate 110 is peeled off.

Meanwhile, although the fill plating scheme is used in order to fill the first divided via with the metal in an exemplary embodiment of the present invention, the present invention is not limited but may use various schemes in order to fill the first divided via with the metal.

Thereafter, as shown in FIG. 9, other portions of the divided via hole 120 are secondarily processed to form the second divided via 120b: 120b₁ and 120b₂.

That is, the second divided via 120b: 120b₁ and 120b₂ is formed using the drill in a direction from the lower copper layer 110c, which is the lower surface of the copper clad laminate 110, to the upper copper layer 110b, which is the upper surface thereof.

Here, similar to a process of forming the first divided via 120a: 120a₁ to 120a₃, the second divided via 120b: 120b₁ and 120b₂ may also be formed using any one of the mechanical drill or the UV, YAG and CO₂ laser drills; however, it is preferable that the second divided via 120b: 120b₁ and 120b₂ is formed at a preset position using the mechanical drill and the deburring and desmear processes removing various pollutants and foreign materials are performed.

The, the second divided via 120b: 120b₁ and 120b₂ is filled with the metal.

The fill plating scheme is used in order to fill the second divided via with the metal in an exemplary embodiment of the present invention. As shown in FIG. 10, a second electroless plating layer 132b is formed on the copper clad laminate 110 having the second divided via 120b: 120b₁ and 120b₂ formed therein.

That is, the second electroless plating layer 132b is formed by performing the electroless plating process in order to provide electrical conductivity to the entire surface of the copper clad laminate 110 and the inner portion of the second divided via 120b: 120b₁ and 120b₂.

Here, the electroless plating process, which is a process performed in order to form the seed layer for electrically copper plating the second divided via 120b: 120b₁ and 120b₂, may includes the electroless plating operation and the electrical copper plating operation.

Next, a second plating resist 140b is applied to an opposite surface to one surface of the copper clad laminate 110 on which the second electroless plating layer 132b is formed, and the electro plating process is performed on the surface of the electroless plated copper clad laminate 110 and the inner portion of the second divided via 120b: 120b₁ and 120b₂ to form the second electro plating layer 134b, thereby filling the inner portion of the second divided via 120b: 120b₁ and 120b₂ with the metal.

Then, the second plating resist 140b applied to the opposite surface of the copper clad laminate 110 is peeled off.

In conclusion, in order to fill plate the via hole having a large size, a plating thickness becomes thick and an etching amount for forming the pattern increases. Therefore, there was a problem in that it is difficult to apply a fine pattern or a predetermined thickness should be removed by methods such as an etching method, a polishing method, or the like, in order to remove an unnecessary thickness. In addition, the via hole having the large size had a large dimple, which is a concave portion, formed on a surface thereof, such that it may not be completely plated by the fill plating scheme.

In the exemplary embodiment of the present invention, in order to solve the problems, after the via hole having the large size are virtually divided into the plurality of divided vias, the portions of the divided vias are drilled by the drill, etc., and only the drilled space is fill plated. Then, other portions of the divided vias are drilled on the opposite surface of the base substrate by the drill, etc., and a fill plating process is then performed, thereby making it possible to effectively fill the inner portion of the via hole without the dimple.

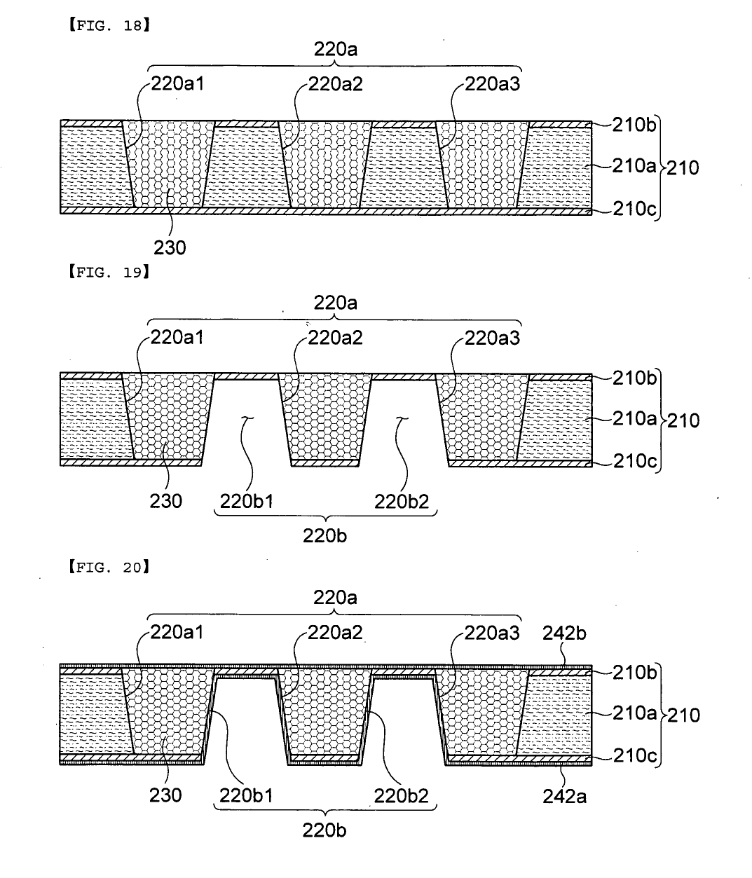

FIGS. 16 to 21 are cross-sectional views showing a process of filling a via hole of a printed circuit board according to another exemplary embodiment of the present invention.

As shown in FIGS. 16 to 21, the base substrate 210 is provided in order to manufacture the printed circuit board 200. According to another exemplary embodiment of the present invention, the copper clad laminate (CCL) is provided, the CCL provided with thin copper layers 210b and 210c formed on both surfaces thereof, having an insulating layer 210a therebetween.

Here, the copper clad laminate 210, which is the raw material for manufacturing the printed circuit board, has a structure in which copper is thinly coated on the insulating layer. A thickness of a copper clad generally is about 18 to 70 μm; however; may be 5 μm, 7 μm, and 15 μm in the case of a fine wiring pattern.

Then, the via hole 220 that is to be formed is divided into a predetermined number, which means that the inner portion of the via hole 220 is virtually divided in order to adjust the dividing number according to a shape and a size of the via hole 220.

Portions of the divided via hole 220 are primarily processed to form the first divided via 220a: 220a₁ to 220a₃.

That is, the first divided via 220a: 220a₁ to 220a₃ is formed using the drill in a direction from an upper copper layer 210b, which is the upper surface of the copper clad laminate 210, to a lower copper layer 210c, which is the lower surface thereof.

Here, the first divided via 220a: 220a₁ to 220a₃ may be formed using any one of a mechanical drill or UV, YAG and CO₂ laser drills; however, it is preferably formed at a preset position using the mechanical drill.

As described above, after the first divided via 220a: 220a₁ to 220a₃ is formed, it is filled with the metal paste 230.

Here, the metal paste 230 may be a conductive paste. A process of filling the metal paste is configured to alternately perform a first operation of filling the first divided via 220a with the metal paste by moving the metal paste to the inner portion of the first divided via 220a using the squeeze and a second operation of pressing the filled metal paste.

The first divided via 220a may be filled with the metal paste using various schemes other than the above-mentioned scheme in which the first divided via 220a is filled with the metal paste using the squeeze.

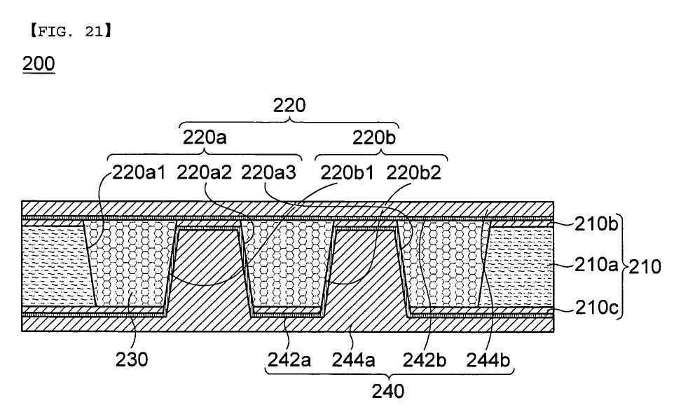

Thereafter, as shown in FIG. 19, other portions of the divided via hole 220 are secondarily processed to form the second divided via 220b: 220b₁ and 220b₂.

That is, the second divided via 220b: 220b₁ and 220b₂ is formed using the drill in a direction from the lower copper layer 210c, which is the lower surface of the copper clad laminate 210, to the upper copper layer 210b, which is the upper surface thereof.

Here, the second divided via 220b: 220b₁ and 220b₂ may be formed using any one of a mechanical drill or UV, YAG and CO₂ laser drills; however, it is preferable that the divided via is formed at a preset position using the mechanical drill and the deburring and desmear processes removing various pollutants and foreign materials are performed.

The deburring process removes the dust particles on the inner wall of the via, the dust particles on the surface of the copper clad, the fingerprint, and the like, generated during the drilling and provides the roughness to the surface of the copper clad, thereby increasing adhesion of the copper in the following filling process.

The resin composing the substrate is melted due to heat generated during the drilling to be attached to the inner wall of the via. The desmear process is a process of removing the resin attached to the substrate. The melted resin attached to the inner wall of the via significantly serves to deteriorate quality of copper plating.

As described above, after the second divided via 220b: 220b₁ and 220b₂ is formed and the deburring and desmear processes are performed, the fill plating process is performed on the surfaces 210b and 210c of the copper clad laminate 210 and the second divided via 220b: 220b₁ and 220b₂.

The fill plating process is performed to form the separating plating layer 242a and the plating layer 242b, which are the electroless plating layer, on the surfaces 210b and 210c of the copper clad laminate 210 and the inner portion of the second divided via 220b: 220b₁ and 220b₂, as shown in FIG. 20. That is, the electroless plating layers 242a and 242b are formed by performing the electroless plating process in order to provide electrical conductivity to the surfaces 210b and 210c of the copper clad laminate 210 and the inner portion of the second divided via 220b: 220b₁ and 220b₂.

Here, the electroless plating process, which is a process performed in order to form the seed layer for electrically copper plating the second divided via 220b: 220b₁ and 220b₂, may include the electroless plating operation and the electrical copper plating operation.

Then, the electro plating process is performed on the surfaces 210b and 210c of the electroless plated copper clad laminate 210 and the inner portion of the second divided via 220b: 220b₁ and 220b₂ to form the filling plating layers 244a and 244b, which are the electro metal layers, thereby fill plating the entire copper clad laminate 210.

Here, the electroless plating process takes a long time and is complicated, such that the plating layer may not be stacked enough to obtain reliability. Therefore, the electro plating process is performed on the inner portion of the second divided via 220b: 220b₁ and 220b₂ that was previously electroless plated, thereby allowing a thickness of the plating layer to become thick.

In the above-mentioned process, the etching resist (made of the same material as that of the plating resist) is selectively applied only to the portions at which the circuits should be formed after the plating is completed on both surface of the substrate, that is, circuit pattern portions. Next, the etching process is performed and the etching resist is then removed, thereby making it possible to form the circuits.

Here, the process of selectively applying the etching or plating resist may be performed by entirely applying the etching or plating resist and then performing selective etching or allowing the plating resist to selectively remain through exposure and development processes.

In addition, when the plating resist is selectively applied only to the portions at which the plating should not be performed before the electro plating process is performed, the electro plating layer is formed to have the circuit shape, thereby making it possible to form the circuits.

The circuit may be formed using various methods other than the methods described above.

In summary, in order to fill plate the via hole having the large size, the plating thickness becomes thick and the etching amount for forming the pattern increases. Therefore, there was a problem in that it is difficult to apply a fine pattern or a predetermined thickness should be removed by methods such as the etching method, the polishing method, or the like, in order to remove unnecessary thickness. In addition, the via hole having the large size had a large dimple, which is the concave portion, formed on a surface thereof, such that it may not be completely plated by the fill plating scheme.

In the exemplary embodiment of the present invention, in order to solve the problems, after the via hole having the large size are virtually divided into the plurality of divided vias, the portions of the divided via are drilled by the drill, etc., and only the drilled space is filled with the metal paste. Then, other portions of the divided vias are drilled on the opposite surface of the base substrate by the drill, etc., and the fill plating process is then performed, thereby making it possible to effectively fill the inner portion of the via hole without the dimple.

As described above, with the printed circuit board and the method for filling a via hole thereof according to the exemplary embodiments of the present invention, the via hole having the large size and various shapes may be filled not to have the dimple or to have the dimple with a thin thickness.

In addition, the via hole having the large size and the various shapes may be filled at a thin thickness.

Although the exemplary embodiments of the present invention have been shown and described, the present invention is not limited thereto but various changes and modifications may be made by those skilled in the art without departing from the spirit of the invention.

What is claimed is:

1. A method for filling a via hole of a printed circuit board, the method comprising:
a dividing step of dividing a via hole that is to be formed in a base substrate into a predetermined number;
a first via forming step of forming a first divided via by primarily processing portions of the divided via hole;
a first filling step of filling the formed first divided via with a metal;
a second via forming step of forming a second divided via by secondarily processing other portions of the divided via hole; and
a second filling step of filling the formed second divided via with a metal to fill the via hole.

2. The method according to claim 1, wherein the first filling step includes fill plating the formed first divided via.

3. The method according to claim 1, wherein the second filling step includes fill plating the formed second divided via.

4. The method according to claim 1, wherein the first filling step includes:
a first electroless plating layer forming step of forming a first electroless plating layer in the formed first divided via; and
a first electro plating layer forming step of forming a first electro plating layer in the formed first divided via having the first electroless plating layer formed therein.

5. The method according to claim 4, wherein the first filling step includes a first plating resist applying step of applying a first plating resist to an opposite surface to one surface of the base substrate on which the first electroless plating layer is formed, before the first electro plating layer forming step.

6. The method according to claim 5, wherein the first filling step includes a first peeling off step of peeling off the applied first plating resist, after the first electro plating layer forming step.

7. The method according to claim 1, wherein the second filling step includes:
a second electroless plating layer forming step of forming a second electroless plating layer in the formed second divided via; and
a second electro plating layer forming step of forming a second electro plating layer in the formed second divided via having the second electroless plating layer formed therein.

8. The method according to claim 7, wherein the second filling step includes a second plating resist applying step of applying a second plating resist to an opposite surface to one surface of the base substrate on which the second electroless plating layer is formed, before the second electro plating layer forming step.

9. The method according to claim 8, wherein the second filling step includes a second peeling off step of peeling off the applied second plating resist, after the second electro plating layer forming step.

10. The method according to claim 1, wherein the first filling step includes filling the formed first divided via with a metal paste.

11. The method according to claim 10, wherein the second filling step includes fill plating the formed second divided via.

12. A printed circuit board comprising:
a base substrate having a via hole formed therein;
first and second divided vias formed by dividing the via hole; and
a metal layer filled in an inner portion of the first and second divided vias.

13. The printed circuit board according to claim 12, wherein the first divided via is fill plated.

14. The printed circuit board according to claim 12, wherein the second divided via is fill plated.

15. The printed circuit board according to claim 12, wherein the first and second divided vias are alternately disposed in an inner portion of the via hole.

16. The printed circuit board according to claim 12, wherein the metal layer includes:
filling metal layers filled in the first and second divided vias; and
separating metal layers interposed between the first and second divided vias to separate the first and second divided vias from each other.

17. The printed circuit board according to claim 16, wherein the separating metal layers includes:
a first separating metal layer interposed in an inner portion of the first divided via; and
a second separating metal layer interposed in an inner portion of the second divided via.

18. The printed circuit board according to claim 17, wherein the first and second separating metal layers are bonded to each other in a sawtooth shape and are filled between the first and second divided vias.

19. The printed circuit board according to claim 16, wherein the filling metal layer is an electro plating layer, and
the separating metal layer is an electroless plating layer.

20. A printed circuit board comprising:
a base substrate having a via hole formed therein; and
first and second divided vias formed by dividing the via hole;
wherein a metal paste layer is interposed in the first divided via, and
a fill plating layer is interposed in the second divided via.

21. The printed circuit board according to claim 20, wherein the first and second divided vias are alternately disposed in an inner portion of the via hole.

22. The printed circuit board according to claim 20, wherein the fill plating layer includes:
a filling plating layer filled in an inner portion of the second divided via; and
a separating plating layer interposed between the first and second divided vias to separate the first and second divided vias from each other.

23. The printed circuit board according to claim 22, wherein the filling plating layer is an electro plating layer, and
the separating plating layer is an electroless plating layer.

24. The printed circuit board according to claim 22, wherein the separating plating layer is interposed in a sawtooth shape.
